(19) United States
(12) Patent Application Publication
(10) Pub. No.: US 2008/0235545 A1
(43) Pub. Date: Sep. 25, 2008

(54) Re-using production test scan paths for system test of an integrated circuit

(76) Inventors: Vinay Burjinroppa Jayaram, Allen, TX (US); Anthony Fryars, Allen, TX (US)

Correspondence Address: TEXAS INSTRUMENTS INCORPORATED, P O BOX 655474, M/S 3999, DALLAS, TX, 75265, US

(21) Appl. No.: 12/074,722

(22) Filed: Mar. 5, 2008

Related U.S. Application Data
(60) Provisional application No. 60/893,135, filed on Mar. 6, 2007.

(51) Int. Cl. G01R 31/3177; G06F 11/25

(52) U.S. Cl. 714/729; 714/E11.155

(57) ABSTRACT

Mission circuitry provided to implement desired data processing operations in an integrated circuit apparatus is tested by using a plurality of scan paths to subject the mission circuitry to production testing before the integrated circuit apparatus is deployed in a mission environment. The plurality of scan paths are re-used to subject the mission circuitry to further testing while the integrated circuit apparatus is deployed in a mission environment.

This application claims the priority under 35 U.S.C. §119(e)(1) of co-pending provisional application Ser. No. 60/893,135 filed Mar. 6, 2007 and incorporated herein by reference.

### FIELD OF THE INVENTION

The invention relates generally to integrated circuits and, more particularly, to testing integrated circuits.

### BACKGROUND OF THE INVENTION

Production testing and system testing are operations that are commonly performed to verify the operation of integrated circuits. Production testing is used to verify operation of mission circuitry in an individual integrated circuit, before that integrated circuit is deployed in a mission environment. The mission circuitry is the circuitry that performs the operations (e.g., digital data processing operations) that are to be performed in a mission environment. The mission environment may be, for example, a physical assembly, such as a printed circuit board, on which the integrated circuit is provided, or any subsystem or system that contains such a physical assembly. System testing is used to verify operation of the mission circuitry while the integrated circuit is deployed in the mission environment.

FIG. 1 diagrammatically illustrates an example of an arrangement that performs production testing according to the prior art. A plurality (eight in the example of FIG. 1) of input tester channels 13 carry input test information provided at respectively corresponding input terminals 16 of the integrated circuit 10. The input test information is formatted as serial scan data, and the input tester channels 13 are serial channels. The input tester channels 13 drive decompressor logic D. The decompressor logic D decompresses the input test information provided by the plurality of input tester channels 13, and outputs the decompressed information (formatted as serial scan data) on a larger plurality (80 in the example of FIG. 1) of serial channels 18. The serial channels 18 drive the scan data inputs of respectively corresponding serial scan paths 12 that are suitably coupled to mission circuitry 11 in order to permit serial scan testing of the mission circuitry 11.

The scan data outputs of the scan paths 12 provide output test information (formatted as serial scan data) on respectively corresponding serial channels 19. Compressor logic C receives the output test information from the serial channels 19, compresses the output test information, and outputs the compressed information (formatted as serial scan data) on a plurality of output tester channels 14. The output tester channels 14 are serial channels that drive respectively corresponding output terminals 17 of the integrated circuit 10. In the example of FIG. 1, the number of output tester channels 14 is the same as the number of input tester channels 13 (namely eight). External production test equipment 15, connected to the externally accessible input and output terminals at 16 and 17, provides the compressed input test information on the input tester channels 13, and analyzes the compressed output test information provided on the output tester channels 14.

The production test equipment 15 provides a scan enable signal 101 and a scan clock 102 to the scan paths 12 of the integrated circuit 10 via input terminals at 16. The scan clock 102 is also provided to the compressor and decompressor logic at C and D.

According to the prior art, system test circuitry is often provided as so-called LBIST (logic BIST (built-in-self-test)) circuitry. The LBIST circuitry is used for system tests such as line checks, reliability checks, power-up tests, field debug tests, failure analysis, and others. In addition to the fact the LBIST circuitry occupies space in the integrated circuit that could otherwise be occupied by mission circuitry, LBIST circuitry presents various implementation issues. Some examples of such implementation issues are set forth below.

The LBIST approach can require lengthy gate-level insertion cycle times, and the addition of X-bounding gates. Inadequate coverage with pseudo-random vectors can lead to additional gates in critical paths. The use of signature registers can make debugging difficult. For example, a single X can corrupt the signature register, and tracing back to the X-source can be difficult. The LBIST approach is generally design intrusive. It affects most functional paths, and disadvantageously requires multiplexing most functional clocks in order to control them during system test. Even a small change in the mission circuitry design requires either a re-insertion of LBIST, or a suitable design modification to ensure that the same signature is maintained, which affects iteration-based designs particularly adversely.

It is desirable in view of the foregoing to provide for system testing of integrated circuits that avoids difficulties associated with the LBIST approach.

### BRIEF DESCRIPTION OF THE DRAWINGS

FIG. 1 diagrammatically illustrates an arrangement for production test of an integrated circuit according to the prior art.

FIG. 2 diagrammatically illustrates an integrated circuit apparatus according to exemplary embodiments of the invention.

FIG. 3 is the state diagram of the conventional JTAG TAP Controller.

FIG. 4 diagrammatically illustrates an arrangement for selecting scan shift and scan capture modes according to exemplary embodiments of the invention.

FIG. 5 diagrammatically illustrates a further integrated circuit apparatus according to exemplary embodiments of the invention.

FIG. 6 diagrammatically illustrates the clock controller of FIG. 2 according to exemplary embodiments of the invention.

FIG. 7 diagrammatically illustrates the gating logic of FIG. 2 according to exemplary embodiments of the invention.

### DETAILED DESCRIPTION

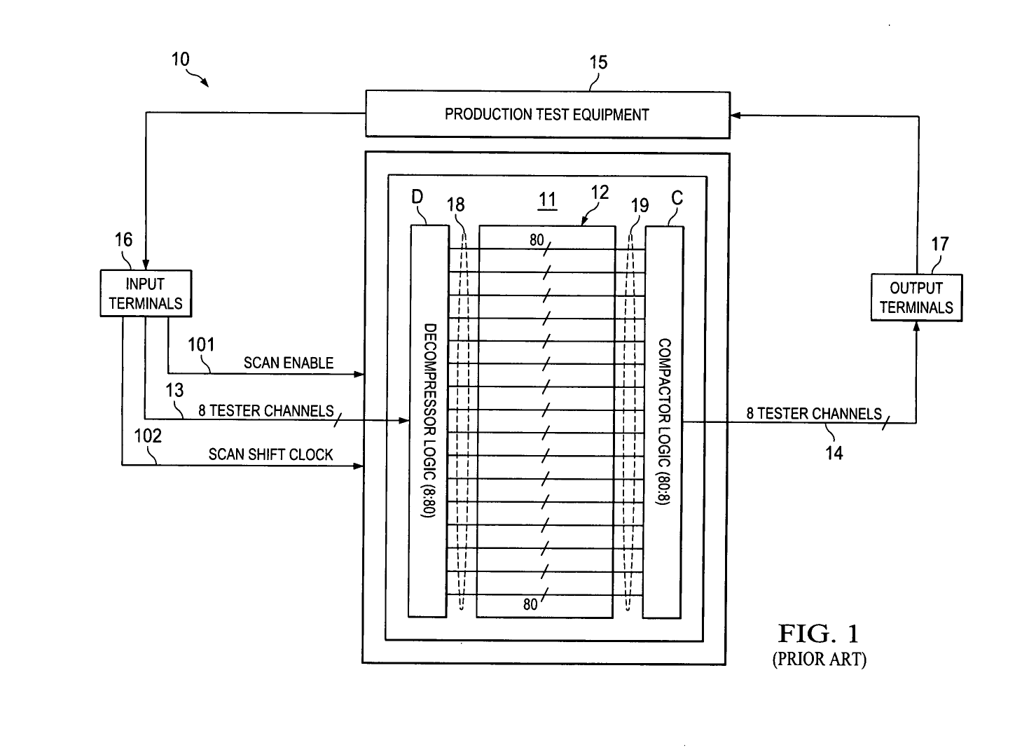

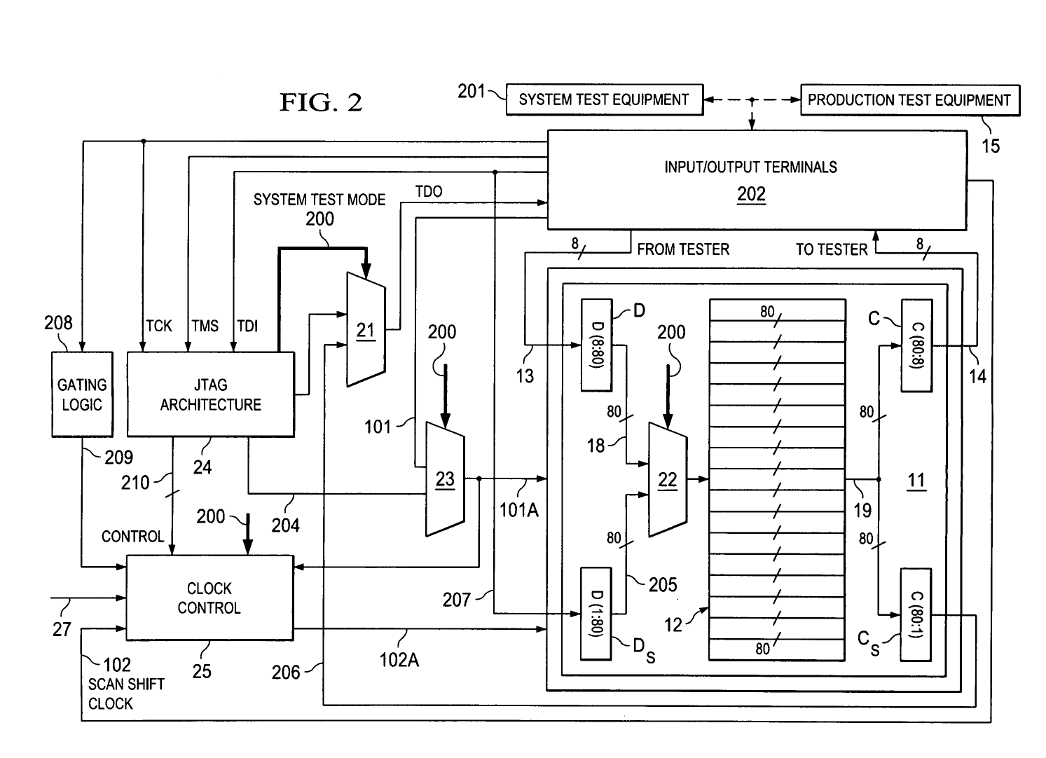

FIG. 2 diagrammatically illustrates an integrated circuit apparatus that supports production testing and system testing according to exemplary embodiments of the invention. The integrated circuit 20 of FIG. 2 is adapted to be coupled, via externally accessible terminals 202, to external production test equipment 15 and external system test equipment 201. The broken line couplings shown in FIG. 2 indicate that the production test equipment 15 and the system test equipment 201 are coupled to the integrated circuit at different points in time. That is, the production test equipment 15 is used to perform production testing before the integrated circuit is deployed in a mission environment, and the system test equipment 201 is used to perform system testing while the integrated circuit is deployed in its mission environment. In some embodiments, the production test equipment 15 cooperates with compressor logic C, scan paths 12, and decompressor logic D in the integrated circuit 20 to perform production testing in the same manner described above with respect to FIG. 1.

The integrated circuit 20 includes selectors (multiplexers in some embodiments) 21-23 that permit the production test scan paths 12 to be re-used for system testing under control of a JTAG (IEEE 1149.1) architecture 24. The JTAG architecture 24 is typically available in many digital integrated circuits, making it a convenient mechanism with which to implement the re-use of the production test scan paths 12 for system testing. The selectors 21-23 are controlled by a system test mode signal 200 produced by the JTAG architecture 24. When the signal 200 is active, the selectors 21-23 select a system test mode configuration. The selectors 21-23 select a production test mode configuration when the signal 200 is inactive.

In some embodiments, the signal 200 is inactive when the integrated circuit apparatus 20 powers up, and remains inactive until the JTAG architecture 24 is exercised appropriately to activate the signal 200 (as described in detail hereinbelow). With the signal 200 inactive, production test mode configuration for production test operations is selected, and the scan paths 12 receive decompressed input test information from decompressor logic D on serial channels 18 via selector 22. So the input test information from the production test equipment 15 on the input tester channels 13 drives the production testing as in FIG. 1. Also with signal 200 inactive, a scan enable signal 101A for the scan paths 12 is provided from an input terminal via the selector 23, so the production test scan enable signal 101 from the production test equipment 15 controls the scan paths 12 as in FIG. 1. Further with signal 200 inactive, clock controller 25 provides the scan shift clock 102 (see also FIG. 1) as the clock 102A for compressor logic C, decompressor logic D, and the scan paths 12.

The JTAG architecture 24 makes the system test mode signal 200 active to select the system test mode configuration for system test operations. In this system test configuration, the scan paths 12 receive decompressed test input information from decompressor logic Ds on serial channels 205 via selector 22, and the input test information is provided by the system test equipment 201 on the JTAG TDI terminal of the integrated circuit 20. The decompressor logic Ds thus provides 1 bit-to-80 bit decompression. Also with system test mode signal 200 active, the scan enable signal 101A for the scan paths 12 is provided from the JTAG architecture 24 via the selector 23, so a system test scan enable signal 204 produced by the JTAG architecture controls the scan paths 12. Also with the system test mode signal active, the system test equipment 15 receives compressed output test information from compressor logic Cs. This compressed information is provided on the JTAG TDO (test data out) terminal of the integrated circuit 20, via signal path 206 and selector 21. The compressor logic Cs receives the output test information on the production test serial channels 19, and thus performs 80 bit-to-1 bit compression. The compressor logic Cs and the decompressor logic Ds can be readily produced using the same conventional design tools used to produce the compressor logic C and decompressor logic D in FIGS. 1 and 2.

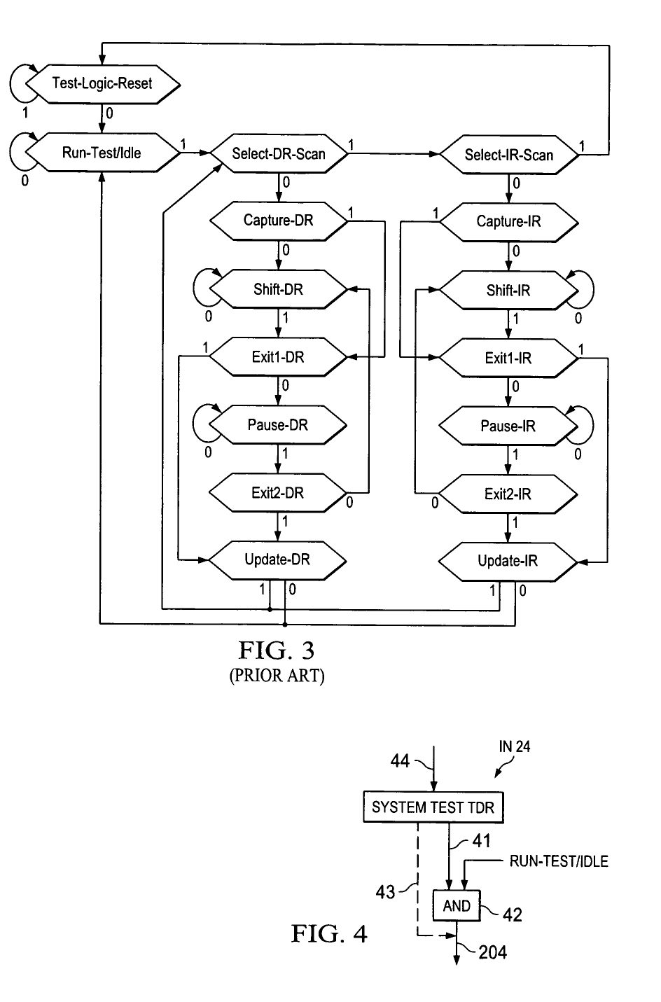

As mentioned above, the JTAG architecture 24 is used to implement re-use of the existing production test scan paths 12 for system testing. The structure, control, and operation of the JTAG architecture are all well known in the art. The state machine of the JTAG TAP (test access port) Controller is shown in FIG. 3. The use of the JTAG TMS (test mode select) and TCK (test clock) signals to manipulate this state machine and thereby control the JTAG architecture 24 is also well known in the art.

In some embodiments, the JTAG architecture 24 controls system testing in system test mode as follows. A system test instruction code is shifted serially into the instruction register (not explicitly shown) contained in the JTAG architecture 24, via the JTAG TDI (test data input) terminal of the integrated circuit 20. This system test instruction code is decoded by the JTAG architecture 24. In some embodiments, the system test mode signal 200 is activated by the decoding of the system test instruction code, and is otherwise inactive. This decoding of the system test instruction code also results in selection of a JTAG test data register (TDR) that corresponds to the system test instruction code. This selected TDR, also referred to herein as the system test TDR, can be programmed (by shifting bits thereinto via the TDI terminal) appropriately to support system testing via the production test scan paths 12.

In some embodiments, a scan enable bit defined within the system test TDR provides the system test scan enable signal 204. This permits the scan enable signal 101A for the scan paths 12 to be controlled by appropriately programming the system test TDR during system test mode. The scan enable bit of the system test TDR is set to place the scan paths 12 in scan shift mode, and is cleared to place the scan paths 12 in scan capture mode. With the integrated circuit 20 configured in system test mode, and with the enable bit of the system test TDR set, the TMS and TCK terminals of the integrated circuit 20 can be used to manipulate the TAP Controller state machine of FIG. 3 in conventional fashion in order to shift input test information from the TDI terminal of the integrated circuit 20 to the decompressor logic D_{S} via signal path 207. The decompressed input test information produced by the decompressor logic D_{S} is provided on serial channels 205 (analogous to the serial channels 18), and the selector 22 passes these serial channels to the respectively corresponding scan paths 12. In the system test mode, the clock controller 25 is responsive to the activated signal 200 for providing a gated version of the JTAG clock signal TCK as the clock 102A for compressor logic C_{S}, decompressor logic D_{S}, and the scan paths 12. This gated version of TCK, also referred to herein as gated TCK 209, is produced by gating logic 208 whose input is TCK. In some embodiments, the gating logic produces gated TCK by performing a logical AND of TCK with the Run-Test/Idle state of the JTAG TAP controller state machine (see also FIG. 3). An example of such embodiments is illustrated in FIG. 7, wherein the gating logic 208 is a logical AND circuit that receives as inputs the Run-Test/Idle state of the FIG. 3 state machine, and TCK.

Once the scan paths 12 are filled with the decompressed input test information from the serial channels 205, the system test TDR is re-programmed to clear the scan enable bit therein, thereby placing the scan paths 12 in scan capture mode. With the scan paths 12 in scan capture mode, the clock controller 25 exercises the clock signal 102A as necessary to perform the desired test. For example, to perform a so-called “stuck-at” test, the clock controller 25 provides a single clock pulse to the mission circuitry while the scan paths 12 are in scan capture mode. As another example, to perform a so-called “transition fault” test, the clock controller 25 “leaks” at least two clock pulses of the functional clock 27 to the mission circuitry while the scan paths 12 are in scan capture mode. The functional clock 27 is the clock (typically generated by a phase locked loop on the integrated circuit 20) that normally controls operation of the mission circuitry 11.

After the mission circuitry 11 has been exercised as required for the desired test operation, the system test TDR is re-programmed to set the scan enable bit thereof, thereby returning the scan paths 12 to scan shift mode. At this point, the JTAG architecture 24 is operated appropriately to shift out to the compressor logic C_{S} the information that has been captured in the scan paths 12, and simultaneously to shift into the decompressor logic D_{S} more input test information from the TDI terminal (if needed).

In some embodiments, the system test scan enable signal 204 is produced by decoding the JTAG TAP Controller state machine of FIG. 3 directly. Instead of repeatedly shifting bits into the system test TDR to repeatedly set and clear a system test scan enable bit therein, a gating bit defined in the system test TDR is used to gate the states of the state machine of FIG. 3. While this gating bit in the system test TDR is set, the system test scan enable signal at 204 is taken to logic 1 whenever the state machine assumes the Run-Test/Idle state, and is taken to logic 0 whenever the state machine leaves Run-Test/Idle, or whenever the gating bit is cleared in the system test TDR. An example circuit for producing signal 204 in this manner is shown in FIG. 4, wherein the signal 204 is the output of a logical AND circuit 41 whose inputs are the gating bit 42 from the system test TDR in the JTAG architecture 24, and the Run-Test/Idle state of the FIG. 3 state machine. The gating bit value is shifted into the system test TDR via shift input 44.

If the gating bit 42 in the system test TDR is set while the integrated circuit is in system test mode, then, when the state machine of FIG. 3 enters the Run-Test/Idle state (to begin shifting test information into the integrated circuit 20 via the TDI terminal), the signal 204 goes to logic 1, which places the scan paths 12 in scan shift mode (via selector 23). The scan paths 12 are placed in scan capture mode as soon as the state machine exits the Run-Test/Idle state. In some embodiments, the state machine is controlled to exit Run-Test/Idle, then go to Select-DR-Scan, followed by Capture-DR, Exit1-DR, Update-DR, and then back to Run-Test/Idle. During the sequence of states between exiting Run-Test/Idle and re-entering Run-Test/Idle, the scan paths 12 are in scan capture mode, during which the mission circuitry 11 can be exercised as necessary to perform the desired test. The sequence of states between exiting and re-entering Run-Test/Idle, namely, Select-DR-Scan→Capture-DR→Exit1-DR→Update-DR, can be repeated as many times as necessary (before re-entering Run-Test/Idle) to maintain the scan paths 12 in scan capture mode long enough to perform the desired testing of the mission circuitry.

FIG. 4 also illustrates, by broken line, embodiments (described above) that use a system test scan enable bit 43 (whose value is shifted into the system test TDR via shift input 44) to produce the system test scan enable signal 204 directly from the system test TDR.

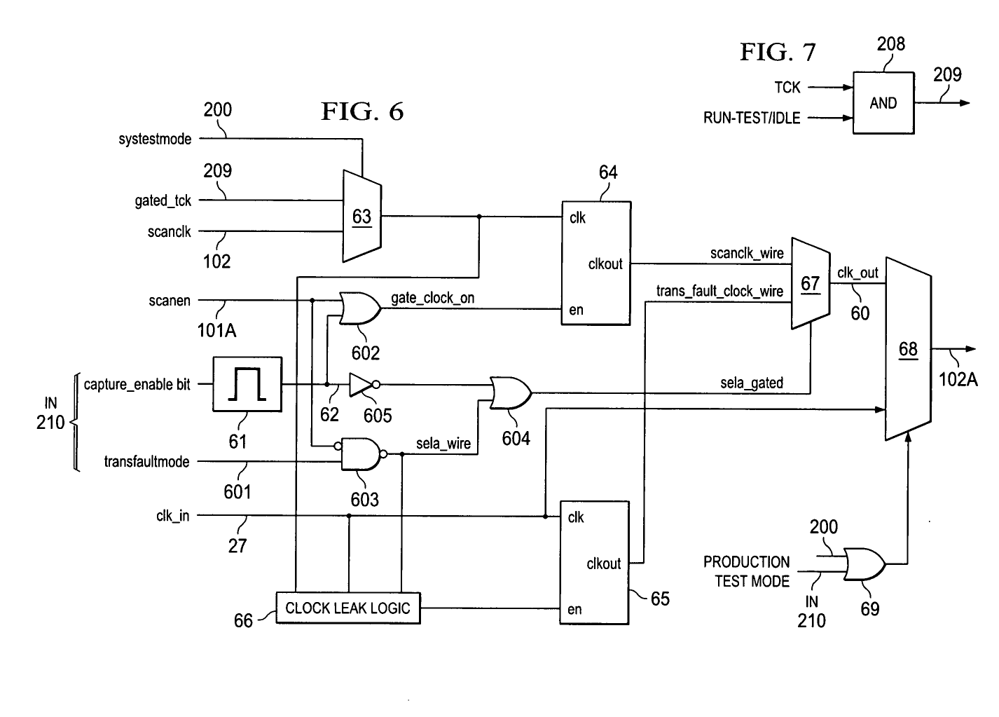

FIG. 6 diagrammatically illustrates the clock controller 25 of FIG. 2 according to exemplary embodiments of the invention. A switch 64 selectively routes to an input (scanclk_wire) of a multiplexer 67 whichever clock is currently selected for scanning test information in the scan paths 12. A multiplexer 63 selects the scan shift clock 102 of FIG. 2 (labeled “scanclk” in FIG. 6) for routing to the scanclk_wire input of multiplexer 67 if the system test mode signal 200 of FIG. 2 is inactive, and selects the gated TCK 209 of FIG. 2 if the signal 200 is active. A switch 65 selectively couples the functional clock 27 of FIG. 2 to another input (trans_fault_clock_wire) of multiplexer 67. The output 60 (clk_out) of the multiplexer 67 drives an input of a multiplexer 68 whose other input is driven by the functional clock 27. The output of multiplexer 68 provides the clock signal 102A of FIG. 2.

The multiplexer 68 is controlled by the output of an OR gate 69 whose inputs are the system test mode signal 200 and a production test mode signal that the JTAG architecture 24 provides to the clock controller 25 at 210 (see also FIG. 2). The production test mode signal is activated when a production test instruction code, shifted into the instruction register of the JTAG architecture 24 of FIG. 2 to initiate production testing, is decoded by the JTAG architecture 24. The production test mode signal is otherwise inactive. If either the system test mode signal or the production test mode signal is active, then the multiplexer 68 selects the clk_out signal 60. If neither the system test mode signal nor the production test mode signal is active, the multiplexer 68 selects the functional clock 27, which results in normal mission mode operation of the mission circuitry 11. Both the system test mode signal and the production test mode signal are inactive upon power up of the integrated circuit apparatus 20.

As shown in FIGS. 2 and 6, the JTAG architecture 24 provides the clock controller 25 (at 210) with a capture enable bit and a “transfault” bit. In the example of FIGS. 6-10, the transfault bit is cleared when stuck at testing is desired, and is set when transition fault testing is desired. When the capture enable bit is set in either the system test TDR (or in a production test TDR that is selected by the decoding of the aforementioned production test instruction code), it activates a pulse generator 61, which in turn produces a capture enable pulse signal at 62. In system test mode, the capture enable and transfault bits are shifted (via TDI) into the system test TDR that is selected upon decoding the system test instruction code. In production test mode, these two bits are shifted (via TDI) into the production test TDR (not explicitly shown in FIG. 2) that is selected upon decoding the production test instruction code. In some embodiments, the capture enable bit and the transfault bit used for production testing are provided from respective input terminals of the integrated circuit (at 202 in FIG. 2), and are multiplexed, together with the corresponding system test bits (from JTAG architecture 24 at 210 in FIG. 2), to the clock controller 25 under control of the system test mode signal 200.

For stuck at testing in either system test mode or production test mode, when the capture enable signal 62, the scan enable signal 101A, and the transfault bit are all low, the switch 64 is disabled (opened) because the gate_clock_on output of OR gate 602 that drives the enable input of the switch 64 is low. Accordingly, the clk_out signal 60 is disconnected from the multiplexer 63. When the capture_enable bit goes high in the selected (system test or production test) TDR, the signal 62 pulses high, which enables (closes) the switch 64 to feed the output of multiplexer 63 to clk_out 60. This connection occurs via multiplexer 67, because the sela_gated output of OR gate 604 is high due to the sela_wire output of NAND gate 603 being high. The switch 64 remains closed for the duration of the pulse produced at 62 by the pulse generator 61. The permits clk_out 60 to receive a clock edge of the next pulse of whichever scan clock is currently selected by multiplexer 63, thereby subjecting the mission circuitry 11 to stuck at testing.

For transition fault testing in either system test mode or production test mode, when the capture enable signal 62 and the scan enable signal 101A are low, and the transfault bit is high, the switch 64 is disabled (opened) because the gate_clock_on output of OR gate 602 is low. Accordingly, the clk_out signal 60 is disconnected from the multiplexer 63. With the scan enable signal 101A low and the transfault bit high, the sela_wire output of NAND gate 603 is low, which enables operation of clock leak logic 66. The clock leak logic 66 operates to enable (close) the switch 65 appropriately to drive the trans_fault_clock_wire signal with a series of equally-sized groups of two or more adjacent pulses of the functional clock 27. The size of the group of functional clock pulses produced depends upon the transition fault testing that is to be performed. A new group of functional clock pulses appears on trans_fault_clock_wire in response to each pulse of the clock selected by multiplexer 63. When the capture_enable bit goes high, the capture_enable signal 62 pulses high. In response to the pulse at 62, the output of inverter 605 takes the sela_gated output of OR gate 604 low for the duration of the pulse 62, so multiplexer 67 passes to clk_out 60 the next group of functional clock pulses on trans_fault_clock_wire, thereby subjecting the mission circuitry 11 to transition fault testing.

The use of gated TCK 209 rather than TCK (see FIGS. 2 and 6) as the scan shift clock in system test mode permits the JTAG architecture 24 to be re-programmed using TCK during system test, without disturbing test information that has already been shifted into the scan paths 12. Such re-programming occurs during system test, for example, in order to clear the scan enable bit 204/101A and place the newly-filled scan paths 12 in capture mode. In some embodiments, once the scan enable bit 204/101A has been cleared, gated TCK 209 can be gated back on for use in stuck at or transition fault testing.

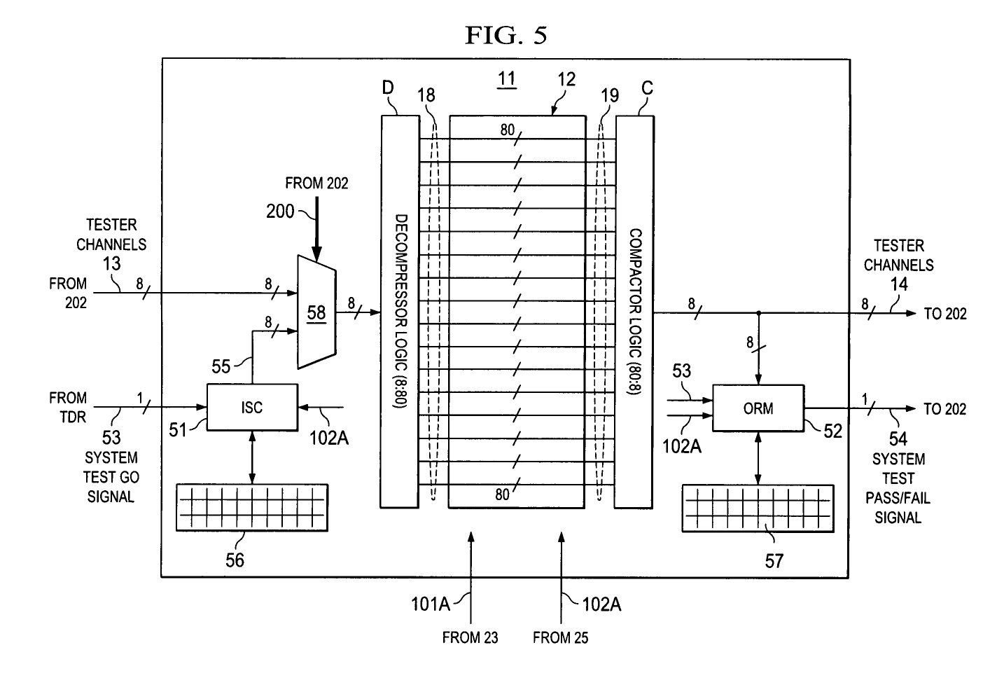

FIG. 5 diagrammatically illustrates an integrated circuit apparatus that supports production testing and system testing according to exemplary embodiments of the invention. In some embodiments, the integrated circuit apparatus 50 is generally the same as the integrated circuit apparatus 20 of FIGS. 2 and 6-10, except the compressed input test information is provided to the scan paths 12 from within the integrated circuit apparatus 50. The integrated circuit apparatus 50 also includes capability for analyzing the compressed output test information.

In system test mode, rather than shifting in the compressed input test information via the TDI terminal as in FIG. 2, an input stimulus controller (ISC) 51 retrieves the compressed input test information from a data storage portion 56 (e.g., ROM or RAM in some embodiments) of the integrated circuit 50. The ISC 51 provides the retrieved information on a plurality (eight in the example of FIG. 5) of serial channels 55 which are coupled to decompressor logic D (see also FIG. 2) by a selector 58 that also couples the tester channels 13 to decompressor logic D in production test mode. A bit in the system test TDR functions as a GO signal 53 that triggers the ISC 51 to begin to retrieve, under control of the clock signal 102A (see also FIG. 2), the compressed input test information from the data storage portion 56, and output the retrieved information on the serial channels 55.

An output response monitor (ORM) 52 receives the compressed output test information on the output tester channels 14 (see also FIG. 2) and, under control of the clock signal 102A, stores the received information in a data storage portion 57 (e.g., RAM in some embodiments). The GO signal 53 is provided to the ORM 52 in order to synchronize the information reception operation of the ORM 52 with the information supplying operation of the ISC 51. The ORM 52 analyzes the information stored in the data storage portion 57 (using signature analysis techniques in some embodiments), and provides at an output terminal of the integrated circuit 50 a PASS/FAIL signal 54 indicative of whether the mission circuitry 11 has passed or failed the system testing.

Although exemplary embodiments of the invention have been described above in detail, this does not limit the scope of the invention, which can be practiced in a variety of embodiments.

What is claimed is:

1. A method of testing mission circuitry that is provided to implement desired data processing operations in an integrated circuit apparatus, comprising:
using a plurality of scan paths to subject the mission circuitry to production testing before the integrated circuit apparatus is deployed in a mission environment; and
re-using the plurality of scan paths to subject the mission circuitry to further testing while the integrated circuit apparatus is deployed in a mission environment.

2. The method of claim 1, including selectively controlling the plurality of scan paths with either one of a first scan control signal associated with said production testing and a second scan control signal associated with said further testing.

3. The method of claim 2, including using a shift register of the integrated circuit apparatus to provide the second scan control signal.

4. The method of claim 3, including shifting the second scan control signal in the shift register.

5. The method of claim 3, including providing the second scan control signal based on a state of a state machine.

6. The method of claim 5, including providing the second scan control signal further based on a signal in the shift register.

7. The method of claim 1, including selectively providing input test information to the plurality of scan paths via either one of first and second externally accessible inputs of the integrated circuit apparatus that are respectively associated with said production testing and said further testing.

8. The method of claim 1, including providing input test information to the plurality of scan paths during said production testing via an externally accessible input of the integrated circuit apparatus, and further including providing input test information to the plurality of scan paths during said further testing without using any externally accessible input of the integrated circuit apparatus.

9. The method of claim 8, including using a shift register of the integrated circuit apparatus to trigger said providing of input test information to the plurality of scan paths during said further testing.

10. The method of claim 1, including, during said further testing and within the integrated circuit apparatus, analyzing output test information provided from the plurality of scan paths to determine a result of said further testing.

11. An integrated circuit apparatus, comprising:
mission circuitry for implementing desired data processing operations;
production test circuitry for subjecting said mission circuitry to production testing before the integrated circuit apparatus is deployed in a mission environment, said production test circuitry including a plurality of scan paths coupled to said mission circuitry; and
further test circuitry for subjecting said mission circuitry to further testing while the integrated circuit apparatus is deployed in a mission environment, said further test circuitry including said plurality of scan paths.

12. The apparatus of claim 11, including a selector coupled to said plurality of scan paths for selectively coupling said plurality of scan paths to either one of a first scan control signal associated with said production testing and a second scan control signal associated with said further testing.

13. The apparatus of claim 12, wherein said further test circuitry includes signal producing circuitry coupled to said selector for producing said second scan control signal, said signal producing circuitry including a shift register.

14. The apparatus of claim 13, wherein said shift register shifts therein said second scan control signal.

15. The apparatus of claim 13, wherein said signal producing circuitry includes a state machine, and is configured to produce said second scan control signal based on a state of said state machine.

16. The apparatus of claim 15, wherein said signal producing circuitry is configured to produce said second scan control signal further based on a signal in said shift register.

17. The apparatus of claim 11, wherein said production test circuitry includes a first input accessible externally of the integrated circuit apparatus and is configured to provide input test information to said plurality of scan paths via said first externally accessible input, and wherein said further test circuitry includes a second input accessible externally of the integrated circuit apparatus and is configured to provide input test information to said plurality of scan paths via said second externally accessible input.

18. The apparatus of claim 11, wherein said production test circuitry includes a first input accessible externally of the integrated circuit apparatus and is configured to provide input test information to said plurality of scan paths via said externally accessible input, and wherein said further test circuitry is configured to provide input test information to said plurality of scan paths without using any input accessible externally of the integrated circuit apparatus.

19. The apparatus of claim 18, wherein said further test circuitry includes a shift register that triggers said further test circuitry to provide input test information to said plurality of scan paths.

20. The apparatus of claim 11, wherein said further test circuitry includes an analyzer coupled to said plurality of scan paths for analyzing output test information provided from said plurality of scan paths to determine a result of said further testing.
